(19) United States
(12) Patent Application Publication
(10) Pub. No.: US 2013/0243367 A1
(43) Pub. Date: Sep. 19, 2013

(54) Fiber Optic Turf Blade Contact and Movement Sensor

(71) Applicant: William Redvers Belisle, New Orleans, LA (US)

(72) Inventor: William Redvers Belisle, New Orleans, LA (US)

(21) Appl. No.: 13/422,275

(22) Filed: Mar. 16, 2012

(51) Int. Cl. G02B 6/00; H05K 13/04; G02B 6/26

(52) U.S. Cl. 385/12; 264/1.25; 29/592; 29/428

(57) ABSTRACT

A fiber optic turf blade contact and movement sensor used to detect, monitor and measure the movement and presence of activity on an athletic field and surface at and near the fiber optic turf blade sensor. This type of sensor contributes to the present efforts to view close calls regarding the athletic related activity, difficult to see athletic related activity, and instant replay of sporting related activities.

### STATEMENT REGARDING FEDERALLY SPONSORED RESEARCH OR DEVELOPMENT

Not Applicable

### BACKGROUND OF THE INVENTION

1. Field of the Invention/Technical Field

The following is A statement of the field of art to which the invention pertains:

1. U.S. Class 385
Field of Search: 385/147

2. U.S. Class 385
Field of Search: 385/147

3. U.S. Class 362
Field of Search: 362/559

4. U.S. Class 473
Field of Search: 473/415

2. Description of Related Art

Nicholls et al. (2007) describes turf comprising a backing and artificial or natural turf fibers and fiber optic filaments used to transmit light “which may be illuminated to indicate various markings, such as lines, symbols, emblems, designs or advertising, on the playing surface of sports and athletic facilities” (USPTO).

Nicholls et al. (2005) describes turf with fiber and fiber optic filaments used to illuminate part or all of a turf surface.

Nicholls et al. (2004) describes turf with fiber optic fibers and fiber optic filaments used to mark and illuminate a surface.

Belisle (2009) describes the use of detection capable grass and turf blades across the entire sporting activity surface to view, sense and interpret sporting activities from within, below and at the sporting activity surface.

The prior are does not describe the manufacture of an intrinsic reflective and refractive fiber optic sensor within and about an artificial turf blade used to detect, monitor and measure athletic related activities at and near the external tip of the fiber optic sensor, nor does the prior art describe the manufacture of a extrinsic viewing fiber optic sensor within and about an artificial turf blade used to detect, monitor and measure athletic related activities at and near the external tip of the fiber optic sensor. The present invention provides the manufacture of an intrinsic reflective and refractive fiber optic sensor within and about an artificial turf blade used to detect, monitor and measure athletic related activities at and near the external tip of the fiber optic sensor, and the manufacture of a extrinsic viewing fiber optic sensor within and about an artificial turf blade used to detect, monitor and measure athletic related activities at and near the external tip of the fiber optic sensor.

### BRIEF DESCRIPTION OF THE INVENTION

It is the objective of the invention to provide the manufacture of a fiber optic turf blade contact and movement sensor device with an intrinsic reflective and refractive fiber optic sensor within and about an artificial turf blade used to detect, monitor and measure athletic related activities at and near the external tip of the fiber optic sensor, and the manufacture of a extrinsic viewing fiber optic sensor within and about an artificial turf blade used to detect, monitor and measure athletic related activities at and near the external tip of the fiber optic sensor, both of which provide additional positions and angles from which to view close-to-the-surface athletic related activities.

### BRIEF DESCRIPTION OF SEVERAL VIEWS OF THE DRAWINGS

The present invention will be more fully understood by references to the following brief description thereof when read in conjunction with the attached drawings, and wherein:

FIG. 1. Side view of a. the fiber optic turf blade contact and movement sensor device, 1, the 0.051 mm to 10 mm (0.02 in to 0.394 in) diameter hole and opening, 2, vertically through the middle of the 0.5 mm to 50 mm (0.0197 in to 1.967 in) wide and 1 mm to 100 mm (0.0394 in to 3.937 in) long turf blade, 4, the 0.051 mm to 10 mm (0.02 in to 0.394 in) diameter fiber optic fiber and fiber optic sensor, 3, positioned within the middle of the turf blade, 4, b. the turf blade, 4, with a hole positioned vertically through the center of the turf blade, c. the fiber optic fiber and fiber optic sensor, 3, positioned on the outside surface of the turf blade, 4, the fiber optic fiber and fiber optic sensor, 3, positioned near the turf blade©, the extended fiber, 6, extending from the bottom of the fiber optic turf blade contact and movement sensor device, 1, and the light source, 5, and depiction a. shows the fiber optic fiber and fiber optic sensor, 3, within the turf blade, 4, with the extended fiber connected to the bottom end of the fiber optic fiber and fiber optic sensor, depiction b. shows the turf blade, 4, with the hole, 2, through the center, depiction c. shows the fiber optic fiber and fiber optic sensor, 3, positioned on the side of the turf blade, 4, with the extended fiber connected to the bottom end of the fiber optic fiber and fiber optic sensor, and depiction d. shows the fiber optic fiber and fiber optic sensor, 3, positioned near the turf blade, 4 with the extended fiber connected to the bottom end of the fiber optic fiber and fiber optic sensor. Component 19 is representative of the adhesives and connectors.

FIG. 2. Side view of the fiber optic turf blade contact and movement sensor device, 1, positioned vertically on the athletic field and surface, 7, the connector and splicer, 8, between the fiber optic turf blade contact and movement sensor device, 1, and the extended fiber, 6, the connector and splicer, 10, between the extended fiber and the fiber optic data collector, 13, the data converter and analyzer, 12, connected to an energy and light source, 12, between the data collector and the computer, 14, the energy source, 5, connected to the data collector and the light source, the light source, 9, connected to the extended fiber, the fiber optic fiber and the fiber sensor, and the fiber optic data collector, 13, the energy and light source, 11, connected to the data collector and the computer, and the television station, 15. Component 19 is representative of the adhesives and connectors.

FIG. 3. Side view of multiple fiber optic turf blade contact and movement sensor devices, 1, positioned on a 1 m×1 m section of an entire athletic field and surface, 16, the connector and splicer, 8, between the fiber optic fiber and fiber optic sensor, 3, and the extended fiber, 6, extending from the lower part of the fiber optic turf blade contact and movement sensor devices, 1, to the fiber optic data collector, 13, the sectional fiber optic turf blade contact and movement sensor device extended fiber collector and bundling, 17, the light source, 5, the extended fiber optic bundle, 18, the fiber optic turf blade contact and movement sensor device data collector, 13, the computer, 14, the television station, 15, the energy source, 11, and the energy and light source, 12. Component 19 is representative of the adhesives and connectors.

### DETAILED DESCRIPTION OF THE INVENTION

(References are to Illustrations)

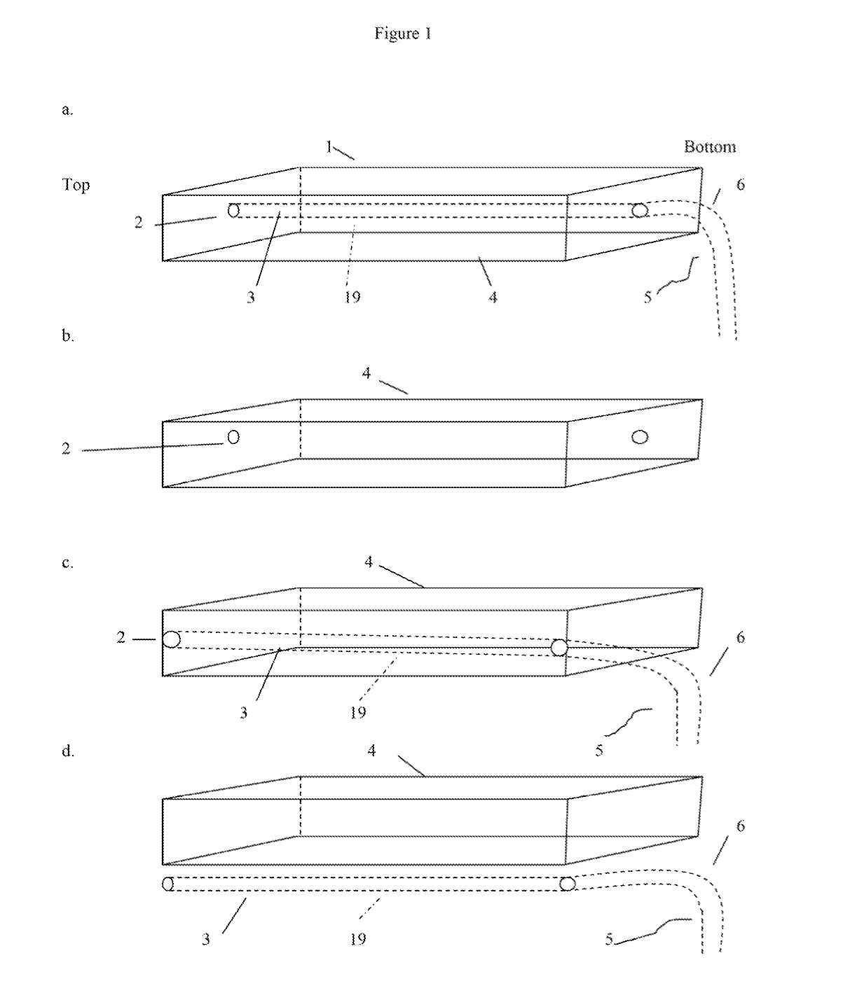

FIG. 1 depicts the components used to make the fiber optic turf blade contact and movement sensor device, 1. The fiber optic turf blade contact and movement sensor device, 1, is made by molding and extrusion and forming the turf blade using polyethylene, polypropylene, synthetic fibers, nylon and turf materials, drilling, and forcing a 0.051 mm to 10 mm (0.02 in to 0.394 in) diameter hole and opening vertically through the middle of a 0.5 mm to 50 mm (0.0197 in to 1.967 in) wide and 1 mm to 100 mm (0.0394 in to 3.937 in) long turf blade, 13. The hole is also drilled into the turf blade, and molded into the turf blade. The 0.051 mm to 10 mm (0.02 in to 0.394 in) diameter fiber optic intrinsic fiber and extrinsic viewing sensor are positioned within the middle of the turf blade, 14 and positioned and held in position using tightness of fitting, adhesive, physical adhering, and clamping. The fiber optic intrinsic and fiber optic extrinsic sensors are positioned on the outside surface of the turf blade, 15, and positioned and held in position using tightness of fitting, adhesive, physical adhering, and clamping. The fiber optic intrinsic fiber and fiber optic extrinsic sensor is positioned near the turf blade, 16. The extended fiber, 4, is connected to the fiber optic intrinsic fiber and fiber optic extrinsic sensor fiber and to the optic turf blade contact and movement sensor device, and extends from the fiber optic turf blade contact and movement sensor device. The fiber optic intrinsic fiber and fiber optic extrinsic sensor fiber and the optic turf blade contact and movement sensor devices are connected to light source, 7, and energy source, 6. Sensor, fiber, electronic, and electrical connection are made using connectors, splicers, and junctions. The making and connectivity of the fiber optic intrinsic fiber sensor, 3, to the turf blade, 4, and the connectivity of the fiber optic extrinsic viewing sensor, 3, to the turf blade, 4, are accomplished by positioning the intrinsic fiber and extrinsic viewing sensors into a hole made through the vertical center of the turf blade, by fitting, inserting, sliding, pushing, sliding, connecting and forcing the fiber and sensor into the hole, and by using adhesives to adhere the fiber and sensor to the turf blade, and by using string, plastic, and additional fine materials to tie and wrap and twist to secure the fiber and sensor about the turf blade, by clamping the fiber and sensor to the turf blade, by coating the fiber and sensor with the turf blade material, by molding the turf blade material around and about the fiber and sensor, by building the fiber and sensor into the turf blade, by nailing, clamping and stapling the fiber and sensor to the turf blade, by melting the turf blade material around the fiber and sensor, forming the turf blade material around the fiber and sensor, and screwing the fiber and sensor to the turf blade. Component 19 is representative of the adhesives and connectors.

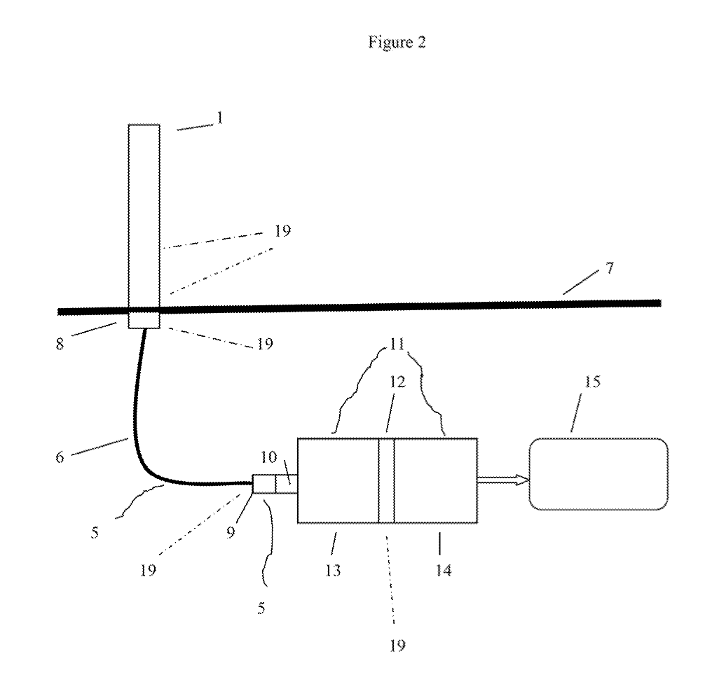

FIG. 2 depicts the components used to make the fiber optic turf blade contact and movement sensor device, 1, which is used to detect, monitor and measure contact with, and movement about an intrinsic fiber optic turf blade contact and movement sensor device, positioned in a system about an athletic field and surface used to detect, monitor and measure contact with, and movement about an intrinsic fiber optic turf blade contact and movement sensor device. Component 1 is also representative of the components used to make the fiber optic turf blade contact and movement sensor device, 1, positioned in a system used to detect, monitor and measure contact with, and movement about an extrinsic fiber optic turf blade contact and movement sensor device. The fiber optic turf blade contact and movement sensor device, 1, is positioned vertically on the athletic field and surface, 2, and is connected to an extended fiber, 4, by a connector and splicer, 3. The connector and splicer, 3, are positioned within and beneath the athletic field and surface. The fiber optic turf blade contact and movement sensor device is connected to the athletic field and surface by threading and tufting, as are present athletic field and surface turf blades. The turf blades are made using molding of polyethylene, polypropylene, nylon, and turf materials, and are also made with a whole in the vertical center of the blade. The extended fiber passes through, and is connected to the light source, 7, which is connected to the fiber optic turf blade fiber and sensor using a connector and splicer, 5, and is then connected to the fiber optic turf blade contact and movement sensor device data collector, data acquisition unit, fiber optic measurement system, data processor, and detector, 8 in the same or similar manner. The optical data collector is connected to an energy and light source, 10, and to the computer, 9. The computer provides sensed data and information to the television station, 11. Light sources, 7, are connected to the fiber optic cable, fibers and optical data collector. Energy sources, 6, are connected to the optical data collector, 8, to the computer, 9, and to the light sources, 7. The connectivity of fiber optic fiber, sensors and cables to athletic fields and surfaces, to extended fibers, to light sources, to energy sources, to connectors and splicers, to optical data collectors and analyzers, and to computers is done using connectors, splicers, electrical and electronic connectors and junctions, clamping, screwing, adhesives, soldering, tying, wrapping and fitting techniques. Component 19 is representative of the adhesives and connectors.

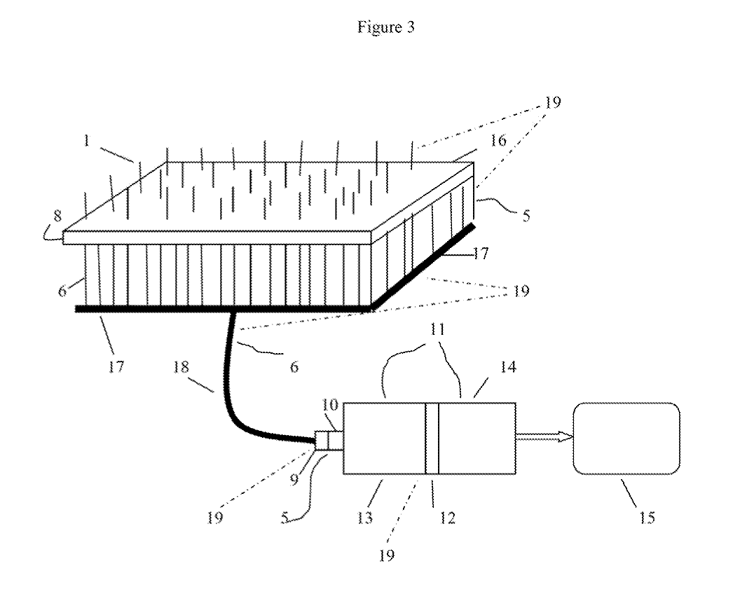

FIG. 3 depicts the components used to make multiple fiber optic turf blade contact and movement sensor devices, 1, positioned on a 1 m×1 m section of an entire athletic field and surface, 12. The multiple fiber optic turf blade contact and movement sensor devices, 1, are connected to a 1 m×1 m section of an entire athletic field and surface, 12, using tufting and threading. Connectors and splicers, 3, are used to connect the fiber optic turf blade contact and movement sensor devices and the extended fibers through and beneath the athletic field and surface, 12. The extended fibers, 4, extend from the lower part of the fiber optic turf blade contact and movement sensor devices and are connected to the fiber optic data collector, 8, by the sectional fiber optic turf blade contact and movement sensor device extended fiber collector, 13. The sectional extended fiber collector, 13, is a bundling of the extended fibers into a single collection, gathering and grouping of the sensors and sensors' information. The collector, 13, is connected to the fiber optic data collector, 8, using connectors, splicers, electrical junctions, clamping, screwing, adhesives, soldering, tying, wrapping and fitting techniques. Connectors, splicers, electronic and electrical connections and known methods are used to connect the light source, 7, the energy source, 6, the energy and light source, 10, the fiber optic turf blade contact and movement sensor device data collector, 8, the computer, 5, and the television station, 11. Component 19 is representative of the adhesives and connectors.

### CROSS-REFERENCES TO RELATED APPLICATIONS

1. Nicholls, M., H. Nicholls, S. O., Pullin, D. L., 2007, “Optically Marked Surface”, U.S. Pat. No. 7,245,815.

2. Nicholls, M. H., Nicholls, S. O., Pullin, D. L., 2005, “Optically Marked Surface”, U.S. Pat. No. 6,950,599.

3. Nicholls, M. H., Nicholls, S. O., Pullin, D. L., 2004, “Optically Marked Surface”, U.S. Pat. No. 6,672,749.

4. Belisle, W. R., 2009, “Sports, Activity Viewing, Sensing and Interpreting System”, U.S. Patent Application No. 20090305823.

What I claim as my invention is:

1. A method of making a fiber optic turf blade contact and movement sensor system comprising:
a fiber optic turf blade contact and movement sensor device made by molding and extrusion and forming the polyethylene, polypropylene, nylon, synthetic fiber turf blade by drilling and forcing a 0.051 mm to 10 mm (0.02 in to 0.394 in) diameter hole and opening vertically through the middle of a 0.5 mm to 50 mm (0.0197 in to 1.967 in) wide and 1 mm to 100 mm (0.0394 in to 3.937 in) long turf blade, a 0.051 mm to 10 mm (0.02 in to 0.394 in) diameter hole molded into the turf blade, a 0.5 mm to 50 mm (0.0197 in to 1.967 in) wide and 1 mm to 100 mm (0.0394 in to 3.937 in) long diameter fiber optic intrinsic fiber sensor positioned within the middle of the turf blade and positioned and held in position using tightness of fitting, adhesive, physical adhering, and damping.

2. The system in claim 1, wherein a 0.5 mm to 50 mm (0.0197 in to 1.967 in) wide and 1 mm to 100 mm (0.0394 in to 3.937 in) long diameter extrinsic viewing sensor positioned within the middle of the turf blade and positioned and held in position using tightness of fitting, adhesive, physical adhering, and clamping.

3. The system in claim 2, wherein said fiber optic intrinsic and fiber optic extrinsic sensors are positioned on the outside surface of the turf blade and positioned and held in position using tightness of fitting, adhesive, physical adhering, and clamping.

4. The system in claim 2, wherein said fiber optic intrinsic fiber and fiber optic extrinsic sensor is positioned near the turf blade.

5. The system in claim 2, wherein an extended fiber is connected to the fiber optic intrinsic fiber and fiber optic extrinsic sensor fiber and to the optic turf blade contact and movement sensor device and extends from the bottom of the fiber optic turf blade contact and movement sensor device.

6. The system in claim 2, wherein said fiber optic intrinsic fiber and fiber optic extrinsic sensor fiber and the optic turf blade contact and movement sensor devices are connected to a light source.

7. The system in claim 2, wherein said fiber optic intrinsic fiber and fiber optic extrinsic sensor fiber and the optic turf blade contact and movement sensor devices are connected to an energy source.

8. The system in claim 2, wherein sensor, fiber, electronic, and electrical connections are made using connectors, splicers, electrical junctions, clamping, screwing, adhesives, soldering, tying, wrapping and fitting techniques.

9. The system in claim 2, wherein the making and connectivity of the fiber optic intrinsic fiber sensor to the turf blade and the connectivity of the fiber optic extrinsic viewing sensor to the turf blade are accomplished by positioning the intrinsic fiber and extrinsic viewing sensors into a hole made through the vertical center of the turf blade by methods of fitting, inserting, sliding, pushing, sliding, connecting and forcing.

10. The system in claim 9, wherein said optical fiber and optical viewing sensor is held in place by using adhesives to adhere the fiber and sensor to the turf blade, by using string, plastic, and additional fine materials to tie and wrap and twist to secure the fiber and sensor about the turf blade.

11. The system in claim 9, wherein said optical fiber and optical viewing sensor is held in place by clamping the fiber and sensor to the turf blade, by coating the fiber and sensor with the turf blade material, by molding the turf blade material around and about the fiber and sensor, by building the fiber and sensor into the turf blade, by nailing, clamping and stapling the fiber and sensor to the turf blade, by melting the turf blade material around the fiber and sensor; forming the turf blade material around the fiber and sensor, and screwing the fiber and sensor to the turf blade.

12. The system in claim 11, wherein said optical fiber senses by intrinsic fiber optic light reflection and refraction over and around the fiber ending and fiber optical viewing detection.

13. The system in claim 11, wherein said fiber optic extrinsic sensor senses by extrinsic fiber optic viewing detection over and around the fiber optical viewing detector.

14. The system in claim 13, wherein the fiber optic sensor is made and used to detect monitor and measure the movement and presence of activity on an athletic field and surface at and near the intrinsic and extrinsic fiber optic fiber and sensor.

15. The system in claim 14, wherein the length of the extended fiber connecting the fiber optic sensor to the fiber optic data collector and the computer range from 100 mm to 10 m.

16. The system in claim 14, wherein the 0.25 mm diameter fiber optic fiber is inserted into the 0.27 mm diameter hole after turf blade molding and forming of the turf blade.

17. The system in claim 14, wherein the 0.25 mm diameter fiber optic fiber is inserted into the 0.27 mm diameter hole during turf blade molding and forming of the turf blade.

18. The system in claim 14, wherein the 0.25 mm diameter fiber optic viewing sensor is inserted into the 0.27 mm diameter hole after turf blade molding and forming of the turf blade.

19. The system in claim 14, wherein the 0.25 mm diameter fiber optic viewing sensor is inserted into the 0.27 mm diameter hole during turf blade molding and forming of the turf blade.

20. A method of making a fiber optic turf blade contact and movement sensor system comprising:
positioning the fiber optic turf blade contact and movement sensor about an athletic field and surface used to detect, monitor and measure contact with, and movement about an intrinsic fiber optic turf blade contact and movement sensor device,
positioning the fiber optic turf blade contact and movement sensor about an athletic field and surface used to detect, monitor and measure contact with, and movement about an extrinsic fiber optic turf blade contact and movement sensor device.

21. The system in claim 20, wherein the fiber optic turf blade contact and movement sensor device is positioned vertically on the athletic field and surface and is connected to an extended fiber by a connector and splicer.

22. The system in claim 20, wherein the connector and splicer are positioned within and beneath the athletic field and surface.

23. The system in claim 22, wherein the fiber optic turf blade contact and movement sensor device is connected to the athletic field and surface by threading and tufting,

24. The system in claim 22, wherein the turf blades are made of polyethylene, polypropylene, nylon, synthetic fiber turf blade materials.

25. The system in claim 22, wherein the turf blade is made with a hole vertically in the center of the blade.

26. The system in claim 25, wherein the extended fiber passes through the vertical hole and is connected to the light source.

27. The system in claim 25, wherein a connector and splicer is used to connect the extended fiber to the fiber optic turf blade contact and movement sensor device data acquisition unit, processor, collector, analyzer and detector and fiber optic measurement system.

28. The system in claim 25, wherein the optical data collector is connected to an energy and light source and to the computer.

29. The system in claim 25, wherein the computer provides sensed data and information to the television station.

30. The system in claim 25, wherein light sources are connected to the fiber optic cable, fibers and optical data collector.

31. The system in claim 25, wherein energy sources are connected to the optical data collector, analyzer and detector, to the computer, and to the light sources.

32. The system in claim 25, wherein the connectivity of fiber optic fiber, sensors and cables to athletic fields and surfaces, to extended fibers, to light sources, to energy sources, to connectors and splicers, to optical data collectors and analyzers, and to computers is done using connectors and splicers, threading and tufting, electrical and electronic junctions and connectors, electronic connectors and digital analyzers.

33. A method of making multiple fiber optic turf blade contact and movement sensor devices positioned on a 1 m×1 m section of an entire athletic field and surface comprising:
making multiple fiber optic turf blade contact and movement sensor devices connected to a 1 m×1 m section of an entire athletic field and surface using threading and tufting methods.

34. The system in claim 32, wherein the connector and splicer are used to connect the fiber optic turf blade contact and movement sensor devices and the extended fibers through d beneath the athletic field and surface.

35. The system in claim 33, wherein the extended fibers extend from the lower part of the fiber optic turf blade contact and movement sensor devices and are connected to the fiber optic data collector by the sectional fiber optic turf blade contact and movement sensor device extended fiber collector.

36. The system in claim 34, wherein the sectional extended fiber collector is a bundling of the extended fibers into a single collection, gathering and grouping of the sensors and sensors' information.

37. The system in claim 35 wherein the extended fiber collector, is connected to the fiber optic data collector, using connectors, and splicers.

38. The system in claim 36 wherein connectors, splicers, electronic and electrical connections are used to connect the light source, the energy source, the energy and light source, the fiber optic turf blade contact and movement sensor device data collector, the computer, and the television station.
